(19) United States
(12) Patent Application Publication
(10) Pub. No.: US 2006/0087010 A1
(43) Pub. Date: Apr. 27, 2006

(54) IC substrate and manufacturing method thereof and semiconductor element package thereby

(76) Inventor: Shinn-Gwo Hong, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/972,349

(22) Filed: Oct. 26, 2004

(51) Int. Cl. H01L 23/495

(52) U.S. Cl. 257/676

(57) ABSTRACT

The present invention pertains to an IC substrate, a manufacturing method thereof and a semiconductor element packaged thereby, wherein a plurality of patterned through-trenches on a metallic board are filled with an insulating material or other materials of different electric conductivity in order to separate the metallic board into a plurality of electrically conductive zones or zones of special electric characteristics. Such a metallic board of the present invention is to be used as a metallic substrate to undertake various modes of IC packaging in order to accomplish various types of packaged elements. The present invention, wherein the metallic substrate is used as an IC substrate, combines the technologies of the conventional lead frame and the conventional PCB, and possesses the advantages of a superior heat-dissipating ability and a possibility of more available leads.

### BACKGROUND OF THE INVENTION

(a) Field of the Present Invention

The present invention relates to a packaging technology of an integrated circuit (IC), particularly to an IC substrate, a manufacturing method thereof and a semiconductor element packaged thereby.

(b) Description of Related Art

The primary objective of an electronic packaging is to transfer signals and electric energy, and to provide a path of heat dissipation and a protection and support of a structure. Regarding the packaging process, which belongs to the post-stage of a semiconductor manufacturing industry, a lead frame and an IC substrate thereof are utilized to be an interconnecting bridge between an IC chip and an external circuitry in order to transfer signals between the IC chip and the external circuitry.

The conventional packaging process, which utilizes a metallic lead frame to undertake a chip assembling and wire bonding, is cheap and has a well heat-dissipating effect. However, the conventional packaging process is limited owing to that, as the progressive advance of the circuitry function of an IC chip, the IC trends to be highly integrated, which results in an obvious increase of input/output junctions, and the conventional method, which utilizes the lead frame to support a chip, can only utilizes four lateral sides to dispose leads, the available lead number is limited an can't afford the need. Further, the lead frame can only be used in a simpler and interconnected circuit.

Therefore, another packaging method of Ball Grid Array (BGA) is propose, which utilizes a printed circuit board (PCB) to be a chip-supporting substrate with array-aligned tin bumps disposed on the bottom side to take the place of the lead frame method, in which the leads can only be disposed along four lateral sides. The advantage of the BGA method is that on the same area, more leads can be disposed, and thus the packaging size can be much smaller. However, as it has been a trend to package a smaller and faster semiconductor chip of high density circuit and the consumed power of a packaged chip grow larger and larger, the heat-dissipating problem thereof is ever more critical. In the BGA method, the manner of solving the heat-dissipating problem is to install a heat-dissipating plate on the aforementioned PCB, wherein the heat-dissipating plate covers the chip on the surface of the PCB, in order to enhance the heat-dissipating ability. However, the effect is yet limited and inferior to the heat-dissipating effect of the conventional lead frame.

Owing to those discussed above, the present invention combines both advantages of the lead frame and the PCB and provides an IC substrate, a manufacturing method thereof and a semiconductor element packaged thereby.

### SUMMARY OF THE PRESENT INVENTION

The primary objective of the present invention is to provide an IC substrate and a manufacturing method thereof, which utilizes a selective-etching technology or a high-aspect-ratio photolithography such as LIGA (Lithographie GaVanoformung Abformung in German) to manufacture a metallic substrate as the IC substrate that has both advantages of a superior heat-dissipating ability and a greater number of leads available, in order to take the place of the current lead frame and PCB.

Another objective of the present invention is to provide a packaged semiconductor element with a metallic substrate, wherein a chip is directly installed onto a completed metallic substrate, which provides a superior heat-dissipating path in order to dissipate heat well, and the packaged semiconductor element can afford enough lead number.

Yet another objective of the present invention is to provide an IC substrate and a manufacturing method thereof, which is made diversified via the choice of insulating materials and supporting structures and thus adaptable to various semiconductor packaging.

Still another objective of the present invention is to provide an IC substrate and a manufacturing method thereof, which directly works out through-trenches or through-holes that penetrate through the top and bottom surface, in contrast to that the interconnecting in the PCB needs a hole drilling and a through-hole plating, and a routing procedure is thus not needed. Accordingly, the area of the substrate can be reduced, or there is larger area to be utilized under the same size.

One embodiment of the present invention is that a patterned through-trench is formed on a metallic board, and the patterned through-trench is filled with an insulating material in order to separate the metallic board into a plurality of electrically conductive zones.

Another embodiment of the present invention is that a patterned through-trench is formed on a metallic board, and the patterned through-trench is filled with an insulating material or materials of different electric conductivities in order to separate the metallic board into a plurality of zones of electric conductivity, resistance or elements of other functions.

Yet another embodiment of the present invention is that a metallic board is provided firstly, and a first patterned film and a first film are separately formed on the top and the bottom surface of the metallic board, and then via the mask of the first patterned film of a photoresist, the metallic board is etched to create a plurality of upper trenches, and then the first patterned film and the first film are removed, and then those aforementioned trenches are filled with a filling material, and then a second film and a second patterned film, which corresponds to the aforementioned first patterned film, are separately formed on the top and the bottom surface the metallic board, and then via the mask of the second patterned film of a photoresist, the metallic board is processed with a half-etching to create a plurality of lower trenches which cooperate with the upper trenches to form a plurality of through-trenches in order to separate the metallic board into a plurality of electrically conductive zones, and then the second film and the second patterned film are removed.

Still another embodiment of the present invention is to provide a packaged semiconductor element with the aforementioned IC substrate.

Via the attached drawings and the embodiments of the present invention described below, the objectives, technical contents, characteristics and accomplishments of the present invention are to be more easily understood.

### BRIEF DESCRIPTION OF THE DRAWINGS

FIG. 1(a) to FIG. 1(k) are sectional views of the steps of manufacturing an IC substrate and a packaged element therewith according to one aspect of the present invention.

FIG. 2 is a top view corresponding to the FIG. 1(a).

FIG. 3 is a top view corresponding to the FIG. 1(e).

FIG. 4(a) to FIG. 4(f) are sectional views of the steps of manufacturing an IC substrate and a packaged element therewith according to one embodiment of the present invention.

### LIST OF REFERENCE NUMERALS

10 metallic board
12 patterned film
14 film
16 upper trench
18 filling material
20 electrically conductive junction
22 solder mask
24 electrically conductive layer
26 IC substrate
28 dam
30 chip
32 lead
34 transparent cover plate
35 resin
36 film
37 through-trench
38 glue
40 encapsulant

### PREFERRED EMBODIMENTS OF THE PRESENT INVENTION

The present invention utilizes a selective-etching technology or a high-aspect-ratio photolithography to manufacture a metallic substrate as an IC substrate to accomplish a semiconductor packaging with both advantages of a superior heat-dissipating ability and a greater number of leads disposed in order to take the place of the conventional lead frame and the PCB and to manufacture a packaged semiconductor element with the IC substrate.

The structure of an IC substrate and a manufacturing method thereof and a semiconductor element packaged thereby are described via two different embodiments.

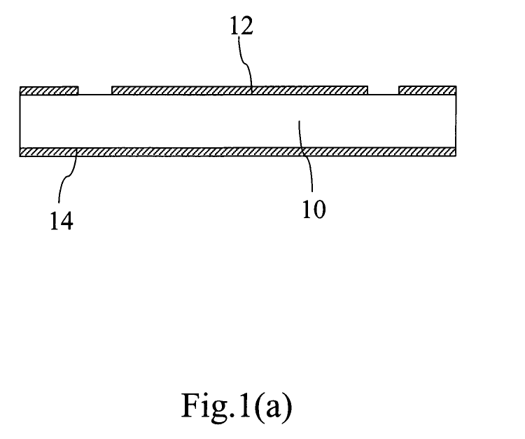

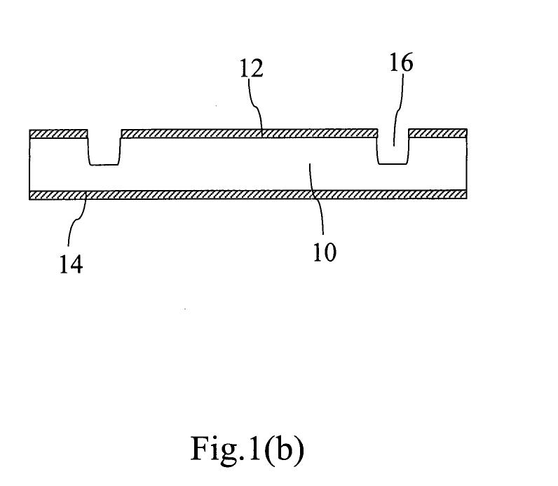

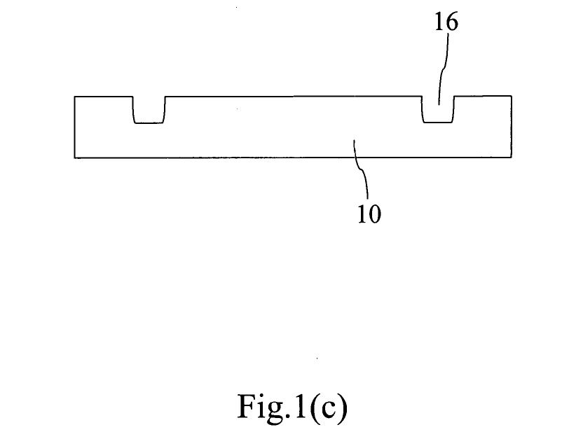

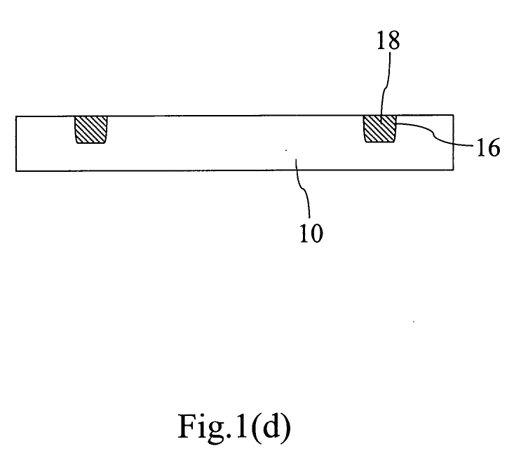

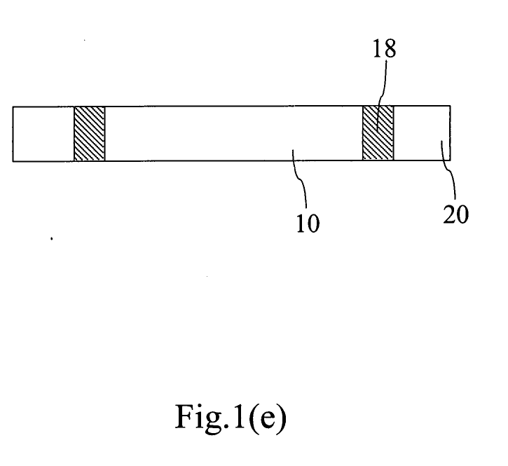

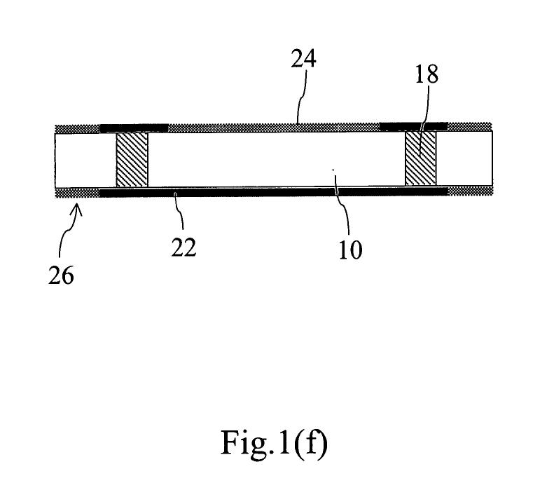

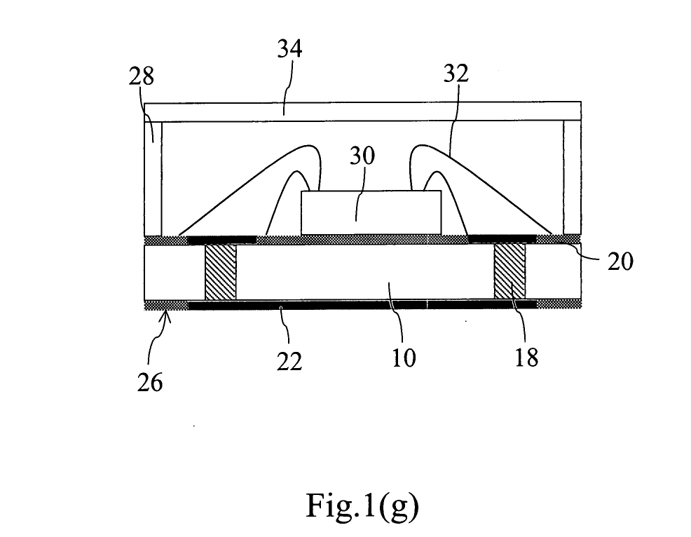

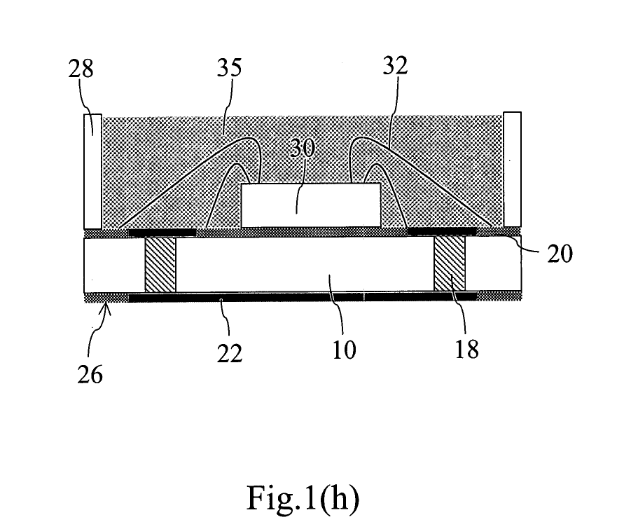

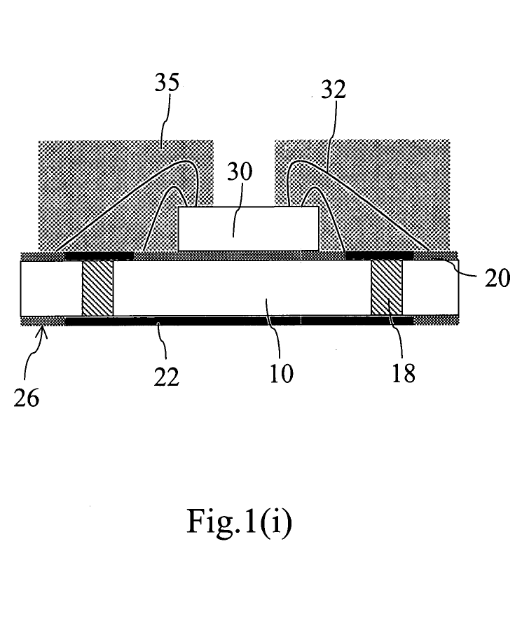

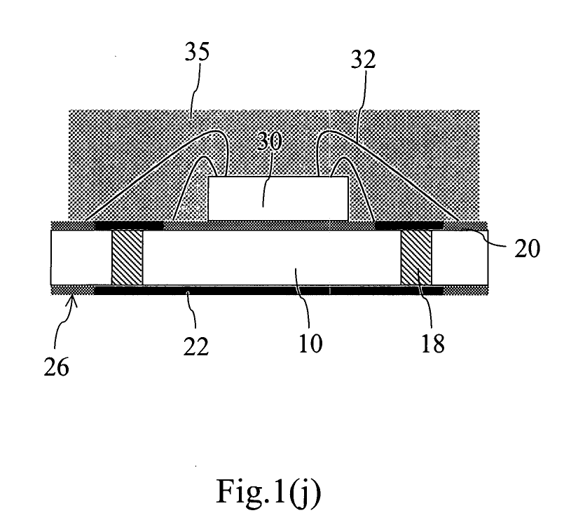

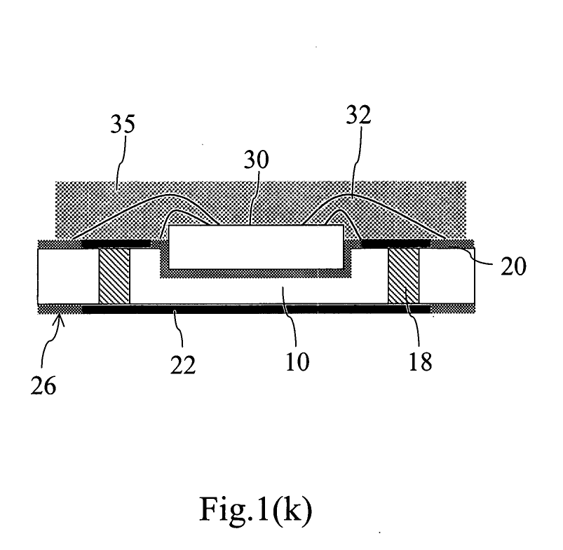

FIG. 1(a) to FIG. 1(g) are sectional views of the steps of manufacturing an IC substrate and a packaged element therewith according to one aspect of the present invention.

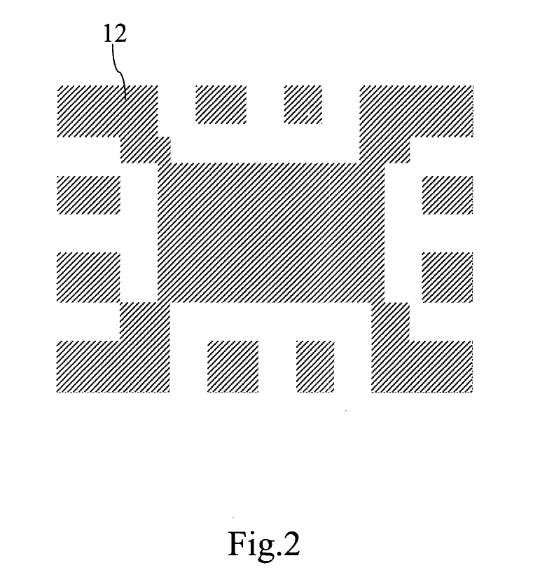

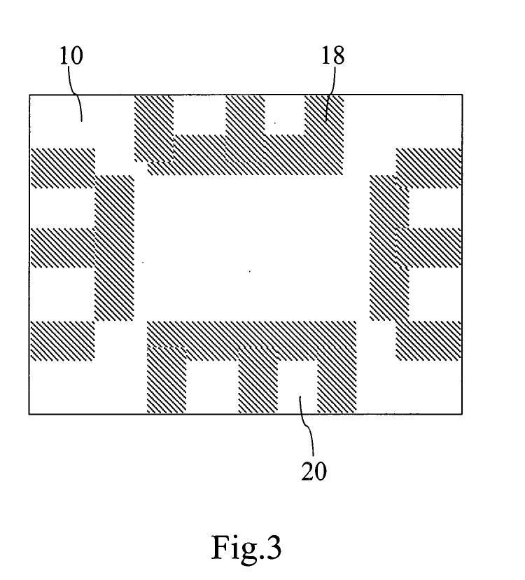

Referring to FIG. 1(a), a patterned film 12 and a film 14 are formed on a metallic board 10 via a photoresist coating and an image transferring. The pattern of the patterned film 12 is shown in FIG. 2.

With the mask of the patterned film 12 of a photoresist, the naked portion of the metallic board 10 is etched away, via the half-etching of one or a plurality of cycles of selective-etchings, in order to form a plurality of defined upper trenches 16, as shown in FIG. 1(b); after removing the patterned film 12 and the film 14, the metallic board 10 with the upper trenches 16 of the defined pattern, as shown in FIG. 1(c), is thus obtained.

Then, the process proceeds to a plugging step, the aforementioned upper trenches 16 are filled with a filling or supporting material 18, which is planarized with a grinding procedure to make the filling material 18 even to the surface of the metallic board 10, as shown in FIG. 1(d); the filling material 18 can be a resin, a silver paste, a copper paste or other materials.

The aforementioned steps are repeated to form a plurality of lower trenches on the bottom surface of the metallic board 10, which cooperate with the upper trenches to form a plurality of through-trenches. (As the steps hereof are similar to those mentioned above, the description of the steps hereof is not to be repeated herein.) Then, the plugging step is also performed on the bottom surface of the metallic board 10, with the filling material 18 being an insulating material, in order to separate the metallic board 10 into a plurality of electrically conductive zones, as shown in FIG. 1(e), wherein the central portion of the metallic board 10 would be a predetermined zone for installing a chip, and the other isolated zones in the periphery thereof would be electrically conductive junctions 20 connected to the external. Further, the filling material 18 can also be an electrically conductive material, which are filled to specified patterned trenches in order to make specified zones be the zones of specified electric characteristics.

Referring to FIG. 1(f), after the separation of the electrically conductive zones, the top and bottom surface of the metallic board 10 are selectively coated with a defined solder mask 22. The surface of the uncoated electrically conductive zones is further processed with a surface treatment to form an electrically conductive layer 24 in order to enhance the electric conductivity of the electrically conductive zones, and thus the manufacture of the IC substrate 26 is completed. The material of the electrically conductive layer 24 can be selected from an electroless tin, an electroplated tin, an electroless silver, an electroless nickel-gold or an electroless nickel-immersion gold.

After the IC substrate is completed, a packaging process, as shown in FIG. 1(g) to FIG. 1(k), begins.

Referring to FIG. 1(g), a dam 28 is installed along the periphery of the surface of the metallic board 10 of the IC substrate 26. The dam 28 surrounds a chip 30 installed on the metallic board 10. A plurality of leads 32 are utilized to electrically interconnect the I/O junctions of the chip 30 and the electrically conductive junctions 20 of the metallic board 10 via a wire bonder. A transparent cover plate 34, such as a glass or plastic plate, is installed above the dam 28 to cover the chip 30 and the leads 32 in order to barrier foreign substance coning from the external, or as shown in FIG. 1(h), a transparent or opaque resin 35 is filled into the space surrounded by the dam 28 in order to protect the circuit portion of the chip 30, where communicating elements operate. Further, another modes of filling the resin 35 are shown in FIG. 1(i) and FIG. 1(j).

Furthermore, as shown in FIG. 1(k), a disposing basin can also be formed on the predetermined zone for installing a chip 30 upon the metallic board 10 in order to reduce the height of a packaging.

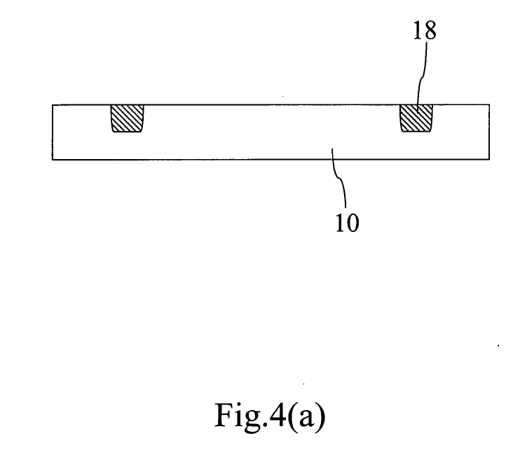

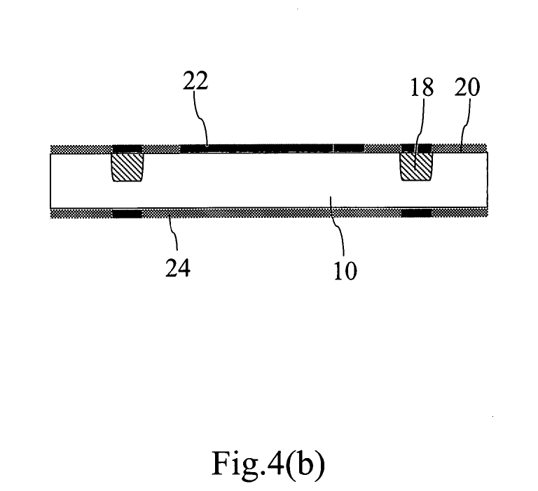

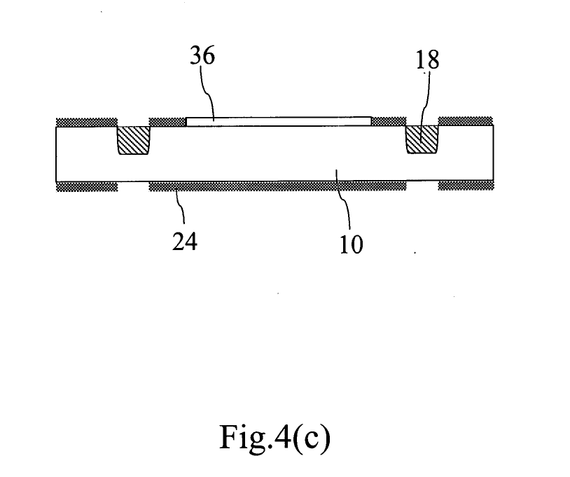

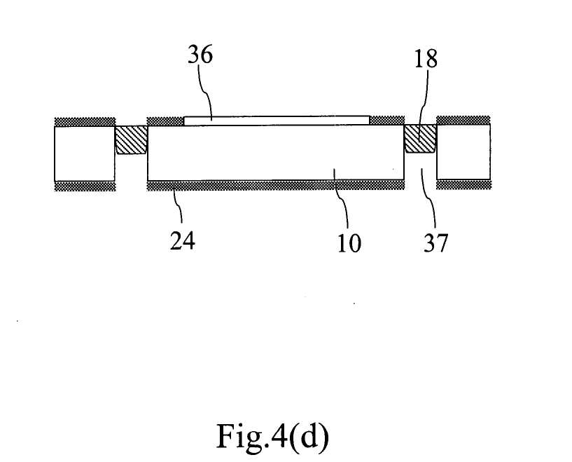

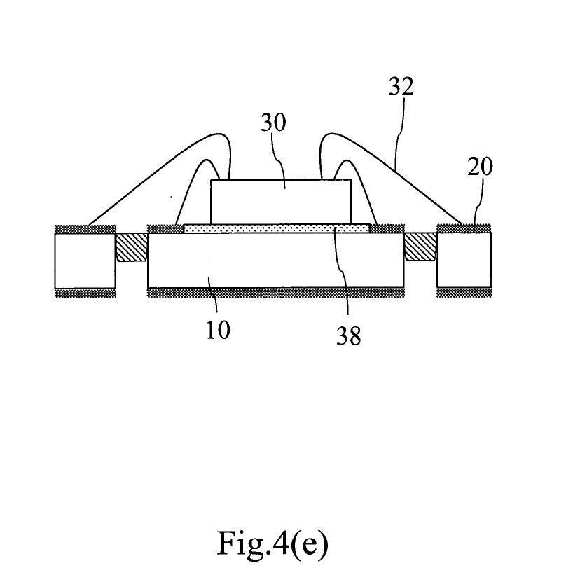

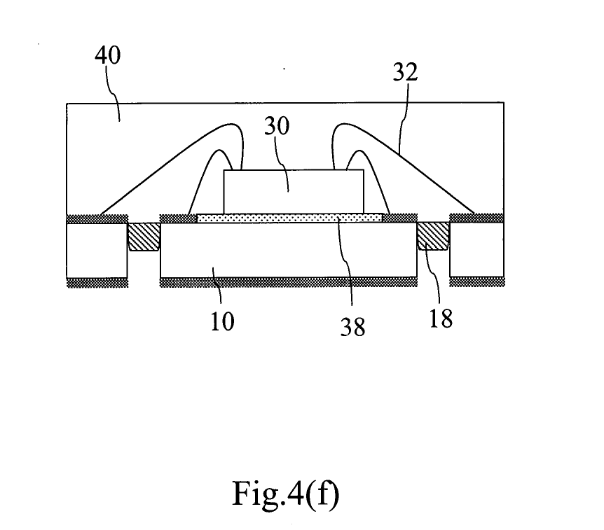

In addition to the aforementioned embodiments, referring to FIG. 4(a) to FIG. 4(f), another embodiment is also provided to describe the technical contents. Firstly, according to the aforementioned steps shown in FIG. 1(a) and FIG. 1(d), a filling material 18 is utilized to separate the metallic board 10 into a predetermined central zone for installing a chip and other isolated electrically conductive zones in the periphery thereof, which would be the electrically conductive junctions 20 to the external, as shown in FIG. 4(a).

Referring to FIG. 4(b), the top and bottom surface of the metallic board 10 are selectively coated with a defined solder mask 22 to shield the predetermined zones, and the rest of the surface of the metallic board 10 is further processed with a surface treatment to form the electrically conductive layers 24 in order to enhance the electric conductivity of the electrically conductive zones. After the surface treatment of the electrically conductive layers 24, the solder mask 22 is removed, and then a film 36 is formed on the predetermined zone, as shown in FIG. 4(c).

Then, an etching step is undertaken. Referring to FIG. 4(d), the metal under the filling material 18 is etched away in order to form a through-trench, which penetrates through the metallic board 10, and then the film 36 is removed.

Then, via a glue 38, a chip 30 is installed on the predetermined zone for installing a chip upon the metallic board 10. A plurality of leads 32 are utilized to electrically interconnect the I/O junctions of the chip 30 and the electrically conductive junctions 20 of the metallic board 10 via a wire bonder, as shown in FIG. 4(e). Lastly, referring to FIG. 4(f), an encapsulant 40 is utilized to cover the top surface of the metallic board 10 in order to encapsulate the chip 30 and the leads 32. The encapsulant 40 is usually an epoxy resin, which provides a mechanical protection to avoid the damage of an external force.

Further, a plurality of solder balls can be installed onto the bottom surface of the metallic board 10 in order to provide soldering to connect another electronic device.

The design of the packaging structure of the present invention is not limited to two aforementioned embodiments; further, the design of the packaging structure of the present invention includes those modified according to different circuit designs of the IC substrate.

The present invention is that via filling an insulating material into a plurality of through-trenches or through-holes, a metallic board is separated into a plurality of electrically conductive zones, and thus to be a metallic substrate. Such a design that a metallic substrate is to be an IC substrate is one combining the advantages of the conventional technologies of the lead frame and the PCB. The advantages of the present invention are summarized below and include:
(a) combining the advantages of a superior heat-dissipating ability and an adaptability to the packaging of high lead number, with the capability of taking the place of the conventional lead frame and PCB;
(b) providing a superior heat-dissipating path to dissipate heat well, with the packaged semiconductor element capable of providing enough lead number;
(c) diversification and adaptability to various semiconductor packaging, via the choice of insulating materials and supporting structures;
(d) smaller IC substrate or larger area available, owing to that the present invention directly works out through-trenches or through-holes that penetrate through the top and bottom surface, in contrast to that the interconnecting in the PCB needs a hole drilling and a through-hole plating, and a routing procedure is thus not needed.

1. An integrated circuit substrate, comprising:
a metallic board, possessing patterned through-trenches penetrating therethrough; and
a filling material, filled into said patterned through-trenches to separate said metallic board into a plurality of zones.

2. The integrated circuit substrate according to claim 1, wherein said filling material is an insulating material, which separates said metallic board into a plurality of electrically conductive zones.

3. The integrated circuit substrate according to claim 1, wherein said filling material is an electrically conductive material, which is filled into specified patterned through-trenches and makes specified zones be the zones of a specified electric characteristics.

4. The integrated circuit substrate according to claim 1, wherein said a plurality of zones on said metallic board are processed with a surface treatment to form an electrically conductive layer.

5. The integrated circuit substrate according to claim 4, wherein the material of said electrically conductive layer is selected from an electroless tin, an electroplated tin, an electroless silver, and electroless nickel-gold or an electroless nickel-immersion gold.

6. The integrated circuit substrate according to claim 1, wherein said patterned through-trenches of said metallic board are manufactured via several cycles of selective-etchings.

7. The integrated circuit substrate according to claim 1, wherein said patterned through-trenches of said metallic board is manufactured via several cycles of high-aspect-ratio photolithography procedures.

8. The integrated circuit substrate according to claim 1, wherein a disposing basin is formed on a predetermined zone for installing a chip upon said metallic board in order to install the chip.

9. The integrated circuit substrate according to claim 1, wherein a solder mask is formed on the surface of said metallic board or said filling material.

10. The integrated circuit substrate according to claim 1, wherein said filling material can be a resin, a silver paste, a copper paste, carbon, etc., which retard or modify electric characteristics.

11-17. (canceled)
